(19) United States
(12) Patent Application Publication
(10) Pub. No.: US 2023/0037134 A1
(43) Pub. Date: Feb. 2, 2023

(54) ANTENNA-INTEGRATED DISPLAY PANEL

(71) Applicant: DONGWOO FINE-CHEM CO., LTD., Jeollabuk-do (KR)

(72) Inventors: Byung Jin CHOI, Incheon (KR); Dong Pil PARK, Incheon (KR); Jae Hyun LEE, Gyeonggi-do (KR)

(21) Appl. No.: 17/964,131

(22) Filed: Oct. 12, 2022

Related U.S. Application Data
(63) Continuation of application No. PCT/KR2021/004629, filed on Apr. 13, 2021.

(30) Foreign Application Priority Data
Apr. 13, 2020 (KR) 10-2020-0044804

(51) Int. Cl. H01Q 1/22; H01Q 1/38; H01Q 1/48

(52) U.S. Cl. CPC H01Q 1/2283; H01Q 1/38; H01Q 1/48

(57) ABSTRACT

An antenna-integrated display panel according to an embodiment includes a display unit, an encapsulation layer disposed on the display unit, an antenna layer formed on the encapsulation layer and including an antenna unit, a polarizing layer disposed on the antenna layer, and a cover window disposed on the polarizing layer.

### CROSS-REFERENCE TO RELATED APPLICATION AND CLAIM OF PRIORITY

The present application is a continuation of application to International Application No. PCT/KR2021/004629, with an International Filing Date of Apr. 13, 2021 which claims the benefit of Korean Patent Application No. 10-2020-0044804 filed on Apr. 13, 2020 at the Korean Intellectual Property Office, the disclosures of which are incorporated by reference herein in their entirety.

### BACKGROUND

### 1. Field

The present invention relates to an antenna-integrated display panel. More particularly, the present invention relates to an antenna-integrated display panel including an antenna layer and a display unit.

### 2. Background of the Related Art

Recently, as mobile communication technologies are developed, an antenna for implementing high-frequency or ultra-high frequency communication is applied to various objects such as display devices such as a smartphone, vehicles, buildings, etc.

An optical structure such as a polarizing plate and various sensor structures may be included in the display device. Thus, when the antenna is included in the display device, proper arrangement and design of the antenna for avoiding an interference with the optical structure and the sensor structure may be required.

Additionally, a space in which the antenna may be employed may be limited by the optical structure and the sensor structure. When an additional film or structure is formed to insert the antenna, an overall thickness and volume of the display device may be increased.

Thus, an antenna construction for achieving sufficient radiation and gain properties in a limited space may be needed.

For example, Korean Published Patent Application No. 2013-0113222 discloses an antenna structure embedded in a portable terminal, but fails to disclose the antenna construction for implementing optical and radiation properties in the display device as described above.

### SUMMARY

According to an aspect of the present invention, there is provided an antenna-integrated display panel having improved optical and radiation properties.

The above aspects of the present invention will be achieved by one or more of the following features or constructions:

(1) An antenna-integrated display panel, including: a display unit; an encapsulation layer disposed on the display unit; an antenna layer formed on the encapsulation layer and including an antenna unit; and a polarizing layer disposed on the antenna electrode layer; and a cover window disposed on the polarizing layer.

(2) The antenna-integrated display panel according to the above (1), wherein the display unit includes a pixel electrode, a display layer and a counter electrode.

(3) The antenna-integrated display panel according to the above (2), wherein the antenna layer is at least partially superimposed over the pixel electrode or the counter electrode in a thickness direction.

(4) The antenna-integrated display panel according to the above (1), wherein the encapsulation layer includes a thin film encapsulation or an encapsulation glass.

(5) The antenna-integrated display panel according to the above (1), wherein the antenna unit includes a radiator, a transmission line branched from the radiator and a signal pad formed at an end portion of the transmission line.

(6) The antenna-integrated display panel according to the above (5), wherein the display unit includes a display area and a non-display area, and the radiator is disposed within the display area.

(7) The antenna-integrated display panel according to the above (5), wherein the radiator and the signal pad overlie the display unit in a thickness direction.

(8) The antenna-integrated display panel according to the above (5), wherein the radiator has a mesh structure.

(9) The antenna-integrated display panel according to the above (8), wherein the antenna layer further includes a dummy mesh pattern arranged around the radiator.

(10) The antenna-integrated display panel according to the above (1), wherein the display unit serves as a ground of the antenna layer.

(11) The antenna-integrated display panel according to the above (1), wherein the encapsulation layer serves as a dielectric layer of the antenna layer.

(12) The antenna-integrated display panel according to the above (1), further including an adhesive layer between the polarizing layer and the cover window.

(13) The antenna-integrated display panel according to the above (1), further including a circuit connection structure disposed on the encapsulation layer to be connected to the antenna layer.

(14) The antenna-integrated display panel according to the above (1), wherein the antenna layer further includes a touch sensing structure.

(15) The antenna-integrated display panel according to the above (1), wherein the display unit includes an organic light emitting diode (OLED) display device.

In an antenna-integrated display panel according to exemplary embodiments, a display unit, an encapsulation layer, an antenna layer and a polarizing layer may be sequentially stacked. The encapsulation layer may serve as a dielectric layer of the antenna layer. Further, the display unit may serve as a ground of the antenna layer. Accordingly, a display panel in which an antenna is embedded may be provided.

In some embodiments, a touch sensing structure may be formed together with the antenna layer. In this case, a display panel in which a touch sensor and an antenna are integrated may be provided.

### BRIEF DESCRIPTION OF THE DRAWINGS

FIG. 1 is a schematic cross-sectional view illustrating an antenna-integrated display panel in accordance with exemplary embodiments.

FIG. 2 is a schematic cross-sectional view illustrating a display unit in accordance with exemplary embodiments.

FIGS. 3 and 4 are schematic top planar views illustrating a stack structure of a display unit and an antenna unit in accordance with exemplary embodiments.

### DETAILED DESCRIPTION OF THE EMBODIMENTS

According to exemplary embodiments of the present invention, there is provided an antenna-integrated display panel including a display unit, an encapsulation layer, an antenna layer and a polarizing layer sequentially stacked.

The antenna layer included in the antenna-integrated display panel may be a microstrip patch antenna fabricated as a transparent film. The antenna-integrated display panel may be applied to, e.g., a high-frequency or ultra-high frequency band (e.g., 3G, 4G, 5G or higher) mobile communication and a communication device for Wi-fi, Bluetooth, NFC, GPS, or the like.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

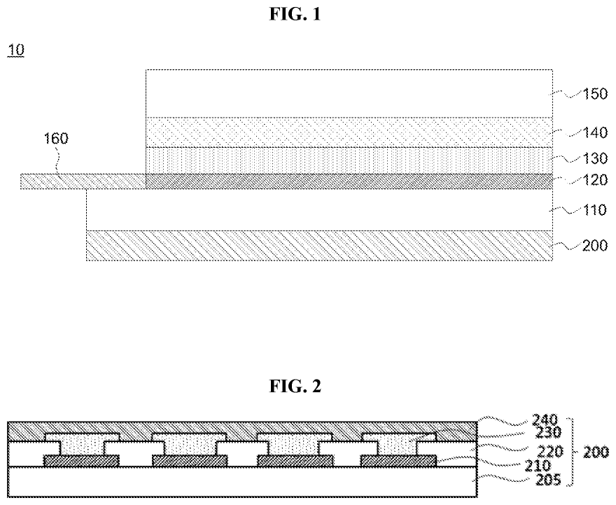

FIG. 1 is a schematic cross-sectional view illustrating an antenna-integrated display panel in accordance with exemplary embodiments.

Referring to FIG. 1, an antenna-integrated display panel 10 (hereinafter, that may be abbreviated as “display panel”) may include a display unit 200, an encapsulation layer 110, an antenna layer 120, a polarizing layer 130 and a cover window 150. The display panel 10 may further include a circuit connection structure 160 and/or an adhesive layer 140.

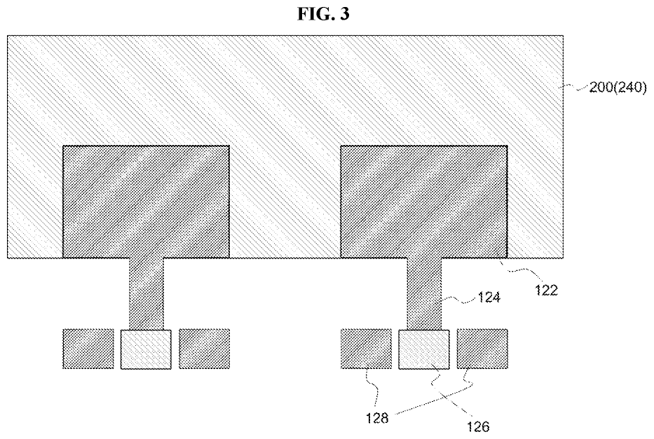

FIG. 2 is a schematic cross-sectional view illustrating a display unit in accordance with exemplary embodiments.

Referring to FIG. 2, the display unit 200 may include a panel substrate 205 and a display device. The display device may include an electrode layer, a pixel defining layer 220 and a display layer 230. The electrode layer may include a pixel electrode 210 and a counter electrode 240.

The display device may be formed on the panel substrate 205.

A pixel circuit including a thin film transistor TFT may be formed on the panel substrate 205, and an insulating layer may be formed to cover the pixel circuit. The pixel electrode 210 may be electrically connected to, e.g., a drain electrode of a TFT on the insulating layer.

The pixel defining layer 220 may be formed on the insulating layer to expose the pixel electrode 210 to define a pixel region. The display layer 230 may be formed on the pixel electrode 210, and the display layer 230 may include, e.g., a liquid crystal layer or an organic light-emission layer.

In exemplary embodiments, the display unit 200 may include an organic light emitting diode (OLED) display device. In this case, the display layer 230 may include the organic light-emission layer.

The counter electrode 240 may be disposed on the pixel defining layer 220 and the display layer 230. The counter electrode 240 may serve as, e.g., a common electrode or a cathode of the display unit 200.

In exemplary embodiments, the display unit 200, the pixel electrode 210 and/or the counter electrode 240 may be coupled to the antenna layer 120 and may serve as an antenna ground. In this case, an antenna without an additional or individual ground may be provided. Accordingly, a thin-layered antenna structure may be obtained by a simple process.

The encapsulation layer 110 may be disposed on the display unit 200. For example, the encapsulation layer 110 may be directly formed on a top surface of the display unit 200. The encapsulation layer 110 may be formed on the top surface of the counter electrode 240 of the display unit 200. The encapsulation layer 110 may protect the display unit 200.

In exemplary embodiments, the encapsulation layer 110 may be interposed between the display unit 200 and the antenna layer 120 to serve as an antenna dielectric layer.

The encapsulation layer 110 may include, e.g., a transparent resin material. For example, the encapsulation layer 110 may include a polyester-based resin such as polyethylene terephthalate, polyethylene isophthalate, polyethylene naphthalate and polybutylene terephthalate; a cellulose-based resin such as diacetyl cellulose and triacetyl cellulose; a polycarbonate-based resin; an acrylic resin such as polymethyl (meth)acrylate and polyethyl (meth)acrylate; a styrene-based resin such as polystyrene and an acrylonitrile-styrene copolymer; a polyolefin-based resin such as polyethylene, polypropylene, a cycloolefin or polyolefin having a norbornene structure and an ethylene-propylene copolymer; a vinyl chloride-based resin; an amide-based resin such as nylon and an aromatic polyamide; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more therefrom.

In some embodiments, an adhesive film such as an optically clear adhesive (OCA), an optically clear resin (OCR), or the like may be included in the encapsulation layer 110.

In some embodiments, the encapsulation layer 110 may include an inorganic insulating material such as silicon oxide, silicon nitride, silicon oxynitride, glass, or the like.

For example, the encapsulation layer 110 may include a thin film encapsulation (TFE) or an encapsulation glass. The thin film encapsulation and the encapsulation glass may serve as a sealing cover of the display unit 200, and may prevent external materials such as oxygen from being introduced into a sealing portion of the display unit 200 to protect pixels (or pixel electrodes) in a display cell.

In an embodiment, the encapsulation layer 110 may be provided as a substantially single layer. In an embodiment, the encapsulation layer 110 may have a multi-layered structure including at least two layers.

Capacitance or inductance may be generated by the encapsulation layer 120 between the antenna layer 120 and the display unit 200, so that a frequency band at the antenna-integrated display panel 10 may be driven or operated may be adjusted.

In some embodiments, a dielectric constant of the encapsulation layer 110 may be adjusted in a range from about 1.5 to 12. When the dielectric constant exceeds about 12, a driving frequency may be excessively reduced, and driving in a desired high frequency band may not be implemented. For example, the encapsulation layer 110 may include glass having a dielectric constant from 3.5 to 8.

In exemplary embodiments, a thickness of the encapsulation layer 110 may be 200 μm or more. In this case, an antenna gain and efficiency may be increased.

The antenna layer 120 may be disposed on one surface (e.g., a top surface) of the encapsulation layer 110. For example, the antenna layer 120 may be formed directly on the top surface of the encapsulation layer 110.

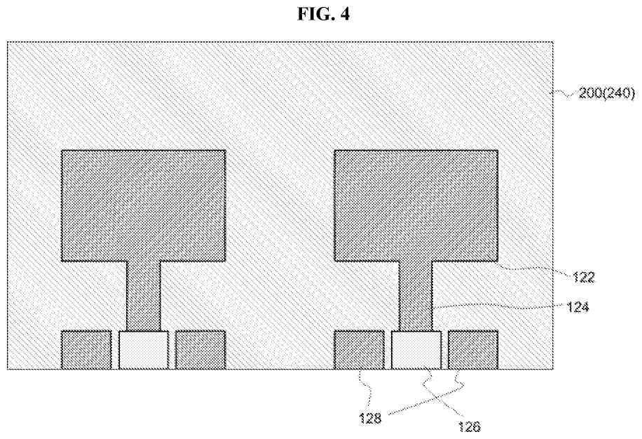

The antenna layer 120 may include an antenna unit. The antenna unit may include a radiator 122, a transmission line 124, and/or a pad unit (see FIG. 3).

For example, the antenna layer 120 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), zinc (Zn), tin (Sn), molybdenum (Mo), calcium (Ca) or an alloy containing at least one of the metals. These may be used alone or in a combination thereof.

In an embodiment, the antenna layer 120 may include silver (Ag) or a silver alloy (e.g., silver-palladium-copper (APC)), or copper (Cu) or a copper alloy (e.g., a copper-calcium (CuCa)) to implement a low resistance and/or a fine line width pattern.

In some embodiments, the antenna layer 120 may include a transparent conductive oxide such indium tin oxide (ITO), indium zinc oxide (IZO), tin oxide (SnOx), zinc oxide (ZnOx), indium zinc tin oxide (IZTO), etc.

In some embodiments, the antenna layer 120 may include a multi-layered structure of a transparent conductive oxide layer and a metal layer. For example, the antenna layer 120 may include a double-layered structure of a transparent conductive oxide layer-metal layer, or a triple-layered structure of a transparent conductive oxide layer-metal layer-transparent conductive oxide layer.

In this case, a flexible property may be improved by the metal layer and a signal transmission speed may be improved by a low resistance of the metal layer. Corrosion resistance and transparency may be improved by the transparent conductive oxide layer.

In some embodiments, a thickness of the antenna layer 120 may be about 5,000 Å or less, and preferably from about 1,000 Å to 5,000 Å. Within the above range, an increase in resistance of the antenna layer 120 may be prevented, and a color shift phenomenon from a visible surface of the display panel 10 may be suppressed.

The radiator 122 may have, e.g., a polygonal plate shape, and the transmission line 124 may extend from one side of the radiator 122 to be electrically connected to a signal pad 126. The transmission line 124 may be formed as a single member substantially integral with the radiator 122.

In some embodiments, the pad unit may include the signal pad 126 and may further include a ground pad 128. For example, a pair of ground pads 128 may be disposed with the signal pad 126 interposed therebetween. The ground pads 128 may be electrically separated from the signal pad 126 and the transmission line 124.

In an embodiment, the ground pad 128 may be omitted. Further, the signal pad 126 may be formed as an integral member with an end portion of the transmission line 124.

In some embodiments, an end portion of the antenna layer 120 may be electrically connected to the circuit connection structure 160. For example, the circuit connection structure 160 may be formed on the same side of the encapsulation layer 110 with the antenna layer 120. The circuit connection structure 160 may contact a top surface of the encapsulation layer 110.

The circuit connection structure 160 may include, e.g., a flexible printed circuit board (FPCB).

The pad unit may be electrically connected to an antenna driving integrated circuit (IC) chip through a circuit connection structure 160 such as a flexible printed circuit board. Accordingly, feeding and driving control to the antenna unit may be performed through the antenna driving IC chip.

The antenna driving IC chip may be directly disposed on the flexible circuit board. For example, the flexible circuit board may further include a circuit or a contact electrically connecting the antenna driving IC chip and the antenna unit to each other.

The antenna unit may be disposed to be adjacent to the flexible circuit board and the antenna driving IC chip, so that a signal loss may be suppressed by shortening a signal transmission/reception path.

In an embodiment, the antenna layer 120 may be formed in a mesh structure. For example, the antenna layer 120 may be directly formed on the top surface of the encapsulation layer 110 by a sputtering process.

In exemplary embodiments, the radiator 122 may have a mesh structure. In some embodiments, the transmission line 124 connected to the radiator 122 may also include a mesh structure.

The radiator 122 may include the mesh structure, so that transmittance may be improved even when the radiator 122 is disposed within the display area of the display panel 10, thereby preventing the antenna layer 120 from being visually recognized and deteriorating an image quality.

A dummy mesh pattern may be disposed around the radiator 122 and the transmission line 124. The dummy mesh pattern may be electrically and physically spaced apart from the radiator 122 and the transmission line 124 through a separation area.

For example, a conductive layer may be formed on the encapsulation layer 110. Thereafter, the conductive layer may be etched to form the mesh structure, and the separation region may be formed by partially etching the conductive layer along profiles of the radiator 122 and the transmission line 124. Accordingly, the antenna unit and the dummy mesh pattern may be separated from each other.

In some embodiments, the signal pad 126 may be formed in a solid structure to reduce a feeding resistance. For example, the signal pad 126 may be disposed in a non-display area or a light-shielding area of the display panel 10 to be bonded or connected to the flexible circuit board and/or the antenna driving IC chip.

Accordingly, the signal pad 126 may be disposed at an outside of a user's visible area. In an embodiment, the signal pad 126 may consist of a metal or an alloy.

FIGS. 3 and 4 are schematic top planar views illustrating a stack structure of a display unit and an antenna unit in accordance with exemplary embodiments. For convenience of descriptions, an illustration of the encapsulation layer 110 between the display unit 200 and the antenna unit is omitted herein.

In exemplary embodiments, the antenna layer 120 may be at least partially superimposed over an electrode layer of the display unit 200 in a thickness direction of the display panel 10. For example, the antenna layer 120 may overlap the pixel electrode 210 or the counter electrode 240 of the display unit 200. For example, at least one of the radiation pattern 122, the transmission line 124 and the pad unit of the antenna layer 120 may be superimposed over overlap the electrode layer of the display unit 200. In this case, an inductance and/or a capacitance may be formed between the antenna layer 120 and the display unit 200 to implement the antenna driving.

Referring to FIG. 3, the radiator 122 may overlie the display unit 200. Referring to FIG. 4, the radiator 122, the transmission line 124 and the pad unit 126 and 128 may all overlie the display unit 200.

In exemplary embodiments, the display unit 200 may include a display area in which an image may be displayed and a non-display area around the display area. In some embodiments, the radiator 122 of the antenna layer 120 may be disposed in the display area. In this case, the radiator 122 may be formed without being limited to a narrow area of the non-display area. Accordingly, an antenna gain may be improved, and frequencies in various bands may be covered.

Further, the pad unit may be disposed in the non-display area. In this case, the pad unit may be formed of a high-conductive material without considering the visual recognition. Accordingly, the gain and efficiency of the antenna may be further improved.

Referring to FIG. 1 again, the polarizing layer 130 may be disposed on the antenna layer 120. For example, the polarizing layer 130 may be directly formed on the top surface of the antenna layer 120.

The polarizing layer 130 may include a coating-type polarizer or a polarizing plate. The coating-type polarizer may include a liquid crystal coating layer including a polymerizable liquid crystal compound and a dichroic dye. In this case, the polarizing layer 130 may further include an alignment layer for providing an orientation to the liquid crystal coating layer.

For example, the polarizing plate may include a polyvinyl alcohol-based polarizer and a protective film attached to at least one surface of the polyvinyl alcohol-based polarizer.

The polarizing layer 130 may reduce and suppress a reflection of an external light from the display panel 10. For example, the polarizing layer 130 may serve as an anti-reflection layer of the display panel 10.

The cover window 150 may be disposed on the polarizing layer 130. The cover window 150 may be disposed on a visible surface or an outermost surface of the display panel 10. The cover window 150 may protect the polarizing layer 130 and the antenna layer 120 at an inside the display panel 10 from physical and chemical damages by an external environment.

The cover window 150 may include, e.g., glass (e.g., UTG) or a flexible resin material such as polyimide, polyethylene terephthalate (PET), acrylic resin, siloxane resin, or the like.

In some embodiments, a thickness of the cover window 150 may be about from 100 μm to 1,000 μm. Preferably, the thickness of the cover window 150 may be from about 300 μm to 600 μm.

In some embodiments, a top surface of the antenna layer 120 may directly contact the cover window 150.

In some embodiments, the adhesive layer 140 may be disposed between the cover window 150 and the polarizing layer 130. The cover window 150 and the polarizing layer 130 may be adhered to each other by the adhesive layer 140.

The adhesive layer 140 may include, e.g., a pressure-sensitive adhesive (PSA) or an optically transparent adhesive (OCA) including an acrylic resin, a silicone resin, an epoxy resin, or the like.

In some embodiments, an adhesive layer may also be disposed between the polarizing layer 130 and the antenna layer 120. For example, the adhesive layer may be formed on a surface of the antenna layer 120 or the polarizing layer 130, and then the antenna layer 120 and the polarizing layer 130 may be attached to each other.

In exemplary embodiments, the antenna layer 120 may further include a touch sensing structure.

The touch sensing structure may include, e.g., capacitive sensing electrodes. For example, column direction sensing electrodes and row direction sensing electrodes may be arranged to cross each other. The touch sensing structure may further include traces connecting the sensing electrodes and a touch sensing driving IC chip to each other. The touch sensing structure may further include a substrate on which the sensing electrodes and the traces are formed.

In this case, an antenna and a touch sensor may be inserted and integrated into the structure of the display panel 10. Accordingly, a device in which an antenna, a touch sensor and a display panel are integrated may be obtained by a simplified process, and a whole thickness of the device may be effectively reduced. For example, the integrated device may have enhanced flexibility and may be provided as a foldable, rollable or flexible device.

In exemplary embodiments, the antenna integrated display panel 10 may be provided as an OCTA (On Cell Touch Type Active Matrix Organic Light Emitting Diode) display module. In this case, the display unit 200 may be an AMOLED device, and a thin film encapsulation or an encapsulation glass of the AMOLED device may be provided as the encapsulation layer 110. The thin film encapsulation or the encapsulation glass of AMOLED may be used as the antenna dielectric layer.

What is claimed is:

1. An antenna-integrated display panel, comprising:
a display unit;
an encapsulation layer disposed on the display unit;
an antenna layer formed on the encapsulation layer and including an antenna unit; and
a polarizing layer disposed on the antenna layer; and
a cover window disposed on the polarizing layer.

2. The antenna-integrated display panel according to claim 1, wherein the display unit comprises a pixel electrode, a display layer and a counter electrode.

3. The antenna-integrated display panel according to claim 2, wherein the antenna layer is at least partially superimposed over the pixel electrode or the counter electrode in a thickness direction.

4. The antenna-integrated display panel according to claim 1, wherein the encapsulation layer includes a thin film encapsulation or an encapsulation glass.

5. The antenna-integrated display panel according to claim 1, wherein the antenna unit comprises a radiator, a transmission line branched from the radiator and a signal pad formed at an end portion of the transmission line.

6. The antenna-integrated display panel according to claim 5, wherein the display unit includes a display area and a non-display area, and the radiator is disposed within the display area.

7. The antenna-integrated display panel according to claim 5, wherein the radiator and the signal pad overlie the display unit in a thickness direction.

8. The antenna-integrated display panel according to claim 5, wherein the radiator has a mesh structure.

9. The antenna-integrated display panel according to claim 8, wherein the antenna layer further comprises a dummy mesh pattern arranged around the radiator.

10. The antenna-integrated display panel according to claim 1, wherein the display unit serves as a ground of the antenna layer.

11. The antenna-integrated display panel according to claim 1, wherein the encapsulation layer serves as a dielectric layer of the antenna layer.

12. The antenna-integrated display panel according to claim 1, further comprising an adhesive layer between the polarizing layer and the cover window.

13. The antenna-integrated display panel according to claim 1, further comprising a circuit connection structure disposed on the encapsulation layer to be connected to the antenna layer.

14. The antenna-integrated display panel according to claim 1, wherein the antenna layer further comprises a touch sensing structure.

15. The antenna-integrated display panel according to claim 1, wherein the display unit includes an organic light emitting diode (OLED) display device.
